(19) United States
(12) Patent Application Publication
(10) Pub. No.: US 2014/0153202 A1
(43) Pub. Date: Jun. 5, 2014

(54) CIRCUIT BOARD MOUNTING APPARATUS

(71) Applicant: HON HAI PRECISION INDUSTRY CO., LTD., New Taipei (TW)

(72) Inventors: Chien-Chung HUANG, New Taipei (TW); Zheng-Heng SUN, New Taipei (TW)

(73) Assignee: HON HAI PRECISION INDUSTRY CO., LTD., New Taipei (TW)

(21) Appl. No.: 13/727,518

(22) Filed: Dec. 26, 2012

(30) Foreign Application Priority Data
Dec. 4, 2012 (CN) 201210512102.2

(51) Int. Cl. H05K 7/14

(52) U.S. Cl. CPC H05K 7/14
USPC 361/760

(57) ABSTRACT

A circuit board mounting apparatus includes a side plate, a circuit board, and a mounting member. The side plate defines a slide slot and a latching hole. A latch protrudes forward from the circuit board, and includes a neck and a latching portion extending leftward from a front end of the neck. The mounting member is mounted to the circuit board, and includes a resilient arm and a hook protruding forward from the resilient arm. The latch extends through the slide slot to allow the neck to abut against a portion of the side plate bounding a left end of the slide slot, and to allow the latching portion to engage with a front side of the side plate. The resilient arm biases the hook to engage in the latching hole and abut against a portion of the side plate bounding a right end of the latching hole.

### BACKGROUND

1. Technical Field

The present disclosure relates to a circuit board mounting apparatus.

2. Description of Related Art

In electronic devices, circuit boards may be mounted inside the devices with a number of screws extended through the circuit board and engaged in a number of posts on a bottom plate of the chassis of the devices. However, fastening screws manually in the chassis can be difficult and inconvenient because of the limited space for maneuvering.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a circuit board mounting apparatus, wherein the circuit board mounting apparatus includes a mounting member.

FIG. 2 is an enlarged view of the mounting member of FIG. 1.

FIG. 3 is a partially assembled, isometric view of FIG. 1.

FIG. 4 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

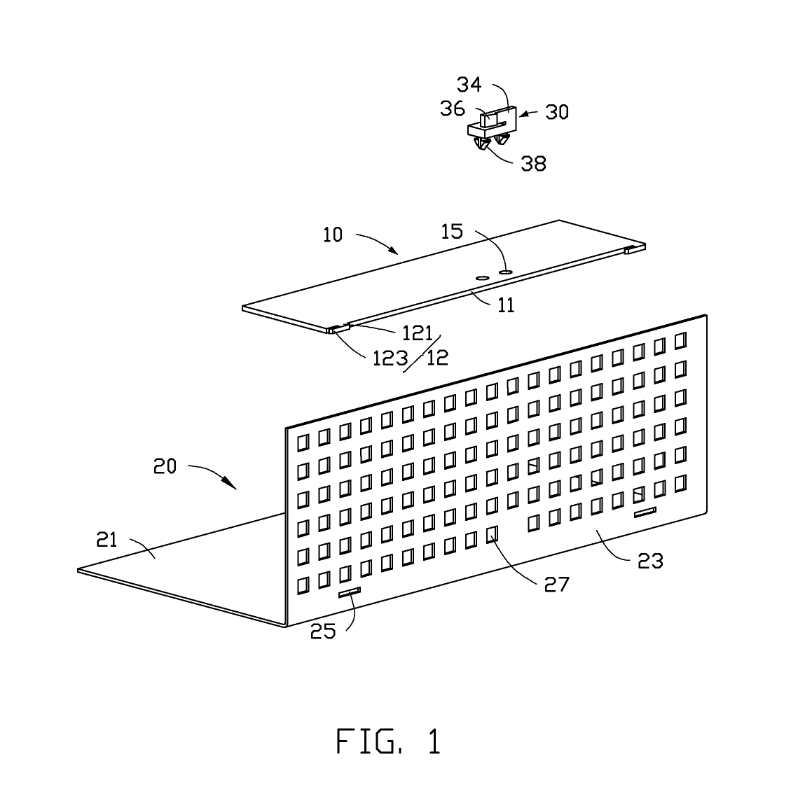

FIG. 1 shows an exemplary embodiment of a circuit board mounting apparatus. The circuit board mounting apparatus includes a circuit board 10, a chassis 20, and a mounting member 30.

Two substantially L-shaped latches 12 protrude from a front side 11 of the circuit board 10. Each latch 12 includes a neck 121 connected to the front side 11, and a latching portion 123 extending leftward from the front end of the neck 121. Two through holes 15 are defined in the circuit board 10, between the latches 12, and adjacent to the front side 11.

The chassis 20 includes a bottom plate 21 and a side plate 23 extending up from the front side of the bottom plate 21 in a substantially perpendicular manner Two horizontally extending slide slots 25 are defined in the side plate 23, adjacent to the bottom plate 21. A latching hole 27 is defined in the side plate 23, between the slide slots 25.

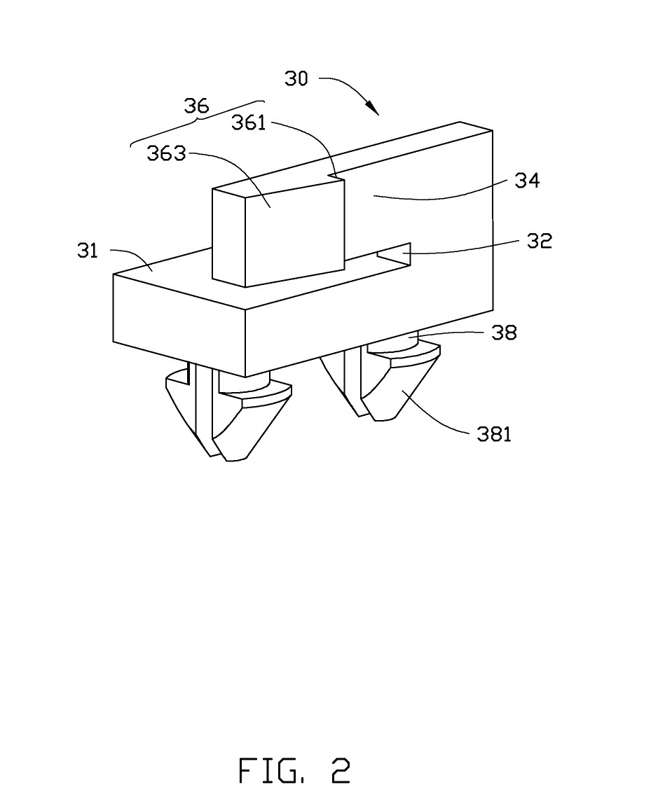

FIG. 2 shows that the mounting member 30 includes a base 31, a supporting arm 32 extending up from the right end of the front side of the top of the base 31, a resilient arm 34 horizontally extending leftward from the top of the supporting arm 32, a hook 36 protruding forward from a distal end of the front side of the resilient arm 34, and two resilient legs 38 extending down from the bottom of the base 31. The hook 36 includes an engaging surface 361 facing rightward and perpendicular to the resilient arm 34, and a guide surface 363 facing leftward and slantingly connected between the resilient arm 34 and the front end of the engaging surface 361. Each leg 38 includes two opposite wedge-shaped hooking portions 381.

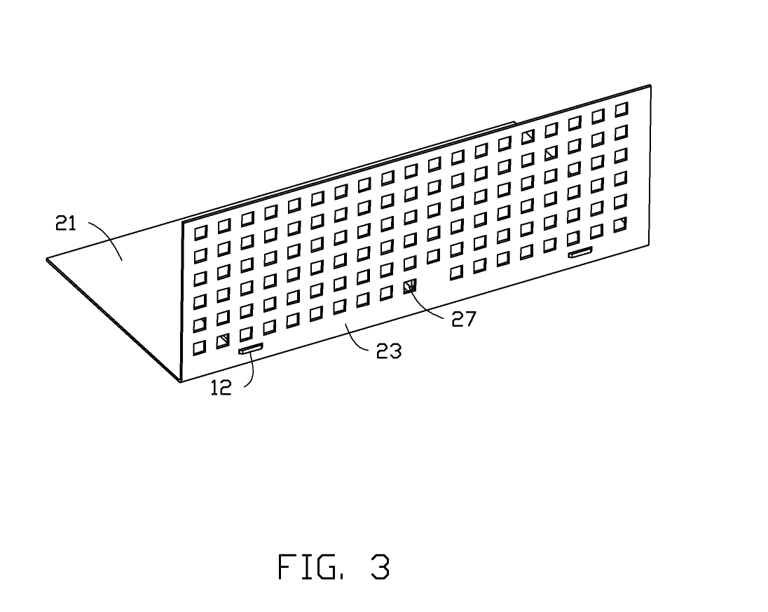

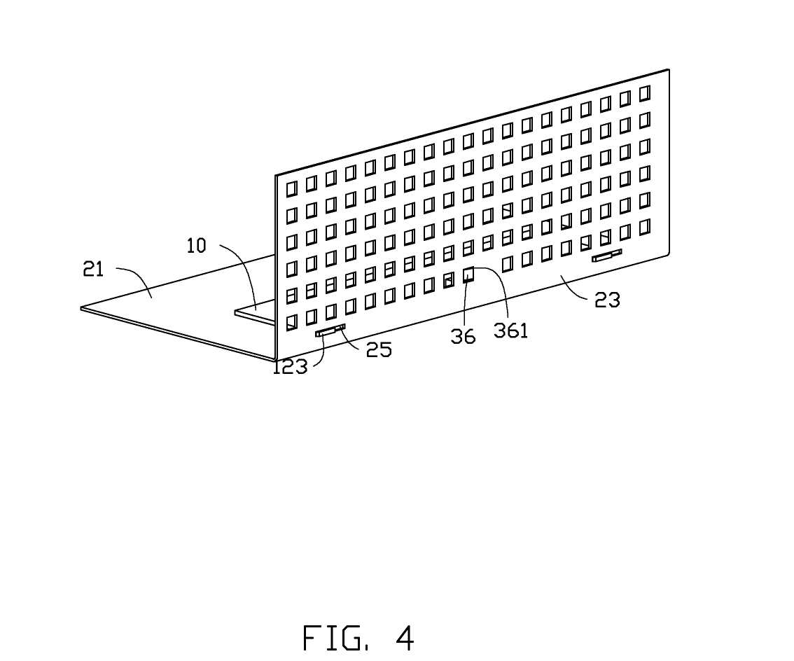

FIGS. 3 and 4 show that in assembly, the legs 38 respectively extend through the through holes 15, to allow the base 31 to be supported on the circuit board 10, and to allow the hooking portions 381 to engage with the bottom of the circuit board 10. Thereby, the mounting member 30 is fixed to the circuit board 10. The circuit board 10 is placed in the chassis 20, parallel to the bottom plate 21, to allow the bottoms of the hooking portions 381 to be supported on the bottom plate 21. The latches 12 are respectively extended through the slide slots 25, to allow the front side 11 of the circuit board 10 to abut the rear side of the side plate 23. The guide surface 363 of the hook 36 abuts against the rear side of the side plate 23 and deforms the resilient arm 34 backward. The circuit board 10 is slid leftward along the side plate 23, until the necks 121 abut against portions of the side plate 23 bounding the left ends of the slide slots 25. The latching portions 123 abut the front side of the side plate 23. The hook 36 aligns with the latching hole 27. The resilient arm 34 is restored to engage the hook 36 in the latching hole 27, to allow the engaging surface 361 to abut against a portion of the side plate 23 bounding the right end of the latching hole 27. Thereby, the circuit board 10 is perpendicularly mounted to the side plate 23.

In the embodiment, the circuit board 10 is mounted to the chassis 20 without screws, which is convenient.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A circuit board mounting apparatus, comprising:
a chassis comprising a side plate defining at least one slide slot and a latching hole;
a circuit board, at least one substantially L-shaped latch protruding from a front side of the circuit board, each of the at least one latch comprising a neck connected to the front side of the circuit board, and a latching portion extending leftward from a front end of the neck; and
a mounting member mounted to the circuit board and adjacent to the front side of the circuit board, the mounting member comprising a resilient arm and a hook protruding from a front side of the resilient arm, the hook comprising an engaging surface facing rightward;
wherein the at least one latch extends through the at least one slide slot and slides to allow the neck to abut against a portion of the side plate bounding a left end of the slide slot, and to allow the latching portion to engage with a front side of the side plate, and meanwhile, the resilient arm biases the hook to engage in the latching hole, to allow the engaging surface of the hook to abut against a portion of the side plate bounding a right end of the latching hole, to perpendicularly fix the circuit board to the side plate.

2. The circuit board mounting apparatus of claim 1, wherein the mounting member further comprises a base supported on the circuit board, and a supporting arm extending up from a top of the base, the resilient arm extends horizontally from the supporting arm.

3. The circuit board mounting apparatus of claim 2, wherein the hook protrudes from a distal end of the front side of the resilient arm.

4. The circuit board mounting apparatus of claim 3, wherein the supporting arm extends up from a right end of a front side of the top of the base, and the resilient arm extends leftward from a top of the supporting arm.

5. The circuit board mounting apparatus of claim 2, wherein two through holes are defined in the circuit board adjacent to the front side of the circuit board, the mounting member further comprises two resilient legs extending down from a bottom of the base, the resilient legs respectively extend through the through holes and abut against a bottom of the circuit board.

6. The circuit board mounting apparatus of claim 5, wherein the chassis further comprises a bottom plate perpendicularly extending backward from a bottom of the side plate, bottoms of the resilient legs are supported on the bottom plate.

7. The circuit board mounting apparatus of claim 1, wherein the number of the at least one slide slot is two, and the number of the at least one latch is two, the latching hole is arranged between the two slide slots, and the mounting member is arranged between the two latches.

8. The circuit board mounting apparatus of claim 1, wherein the hook further comprises a guide surface facing leftward and slantingly connected between the resilient arm and the front end of the engaging surface.

9. The circuit board mounting apparatus of claim 1, wherein the front side of the circuit board abuts against a rear side of the side plate.
